(19) United States
(12) Patent Application Publication
(10) Pub. No.: US 2014/0103779 A1
(43) Pub. Date: Apr. 17, 2014

(54) MICROELECTROMECHANICAL COMPONENT AND METHOD FOR PRODUCING A MICROELECTROMECHANICAL COMPONENT

(71) Applicant: Robert Bosch GmbH, Stuttgart (DE)

(72) Inventors: Christoph Schelling, Stuttgart (DE); Theresa Lutz, Mannheim (DE)

(73) Assignee: Robert Bosch GmbH, Stuttgart (DE)

(21) Appl. No.: 14/053,752

(22) Filed: Oct. 15, 2013

(30) Foreign Application Priority Data
Oct. 15, 2012 (DE) 10 2012 218 725.1

(51) Int. Cl. H02N 1/00; B81C 1/00; B81B 3/00

(52) U.S. Cl. CPC H02N 1/00; B81B 3/0027; B81C 1/0038
USPC 310/308; 29/825

(57) ABSTRACT

A microelectromechanical component and a method for producing a microelectromechanical component includes a charge-storing layer that has improved long-term stability. The charge-storing layer is completely enclosed by dielectric layers such that there is a high potential barrier between the charge-storing layer and the dielectric layers. During normal operation, it is not possible to overcome this high potential barrier and, as a result, the stored charge carriers are maintained over a very long period of time.

This application claims priority under 35 U.S.C. §119 to patent application no. DE 10 2012 218 725.1, filed on Oct. 15, 2012 in Germany, the disclosure of which is incorporated herein by reference in its entirety.

### BACKGROUND

The present disclosure relates to an MEMS component and a method for producing an MEMS component. In particular, the present disclosure relates to such an MEMS component which comprises a charge-storing layer in its construction.

Microelectromechanical components, designated as MEMS components for short hereinafter, are electromechanical components having extremely small dimensions in the micrometers range. Such systems can be used both as sensors and as actuators.

As sensors, such MEMS components are used for example in microphones, in which a small deflection of a microphone membrane is intended to be converted into an electrical signal. Furthermore, such sensors are frequently used within identifying vibrations or shocks. Moreover, such elements can be used as acceleration sensors, in order for example to trigger an airbag of a motor vehicle in the case of an accident.

Furthermore, such MEMS components are also used as actuators. They are used for example for realizing extremely small drives or are used in print heads of inkjet printers.

FIG. 1 shows a schematic illustration of an MEMS component in accordance with the prior art such as can be used for electret microphones. In this case, such a conventional MEMS component comprises two electrodes 1 and 4 spaced apart from one another. In this, one of the two electrodes, here the top electrode 4, is usually movable. By contrast, the other electrode, here the bottom electrode 1, is usually arranged in a fixed manner. An insulating layer 2 is arranged on the bottom electrode 1 in a manner facing in the direction of the top electrode 4. Furthermore, a charge-storing layer 3 is arranged on said insulating layer 2 once again in a manner facing in the direction of the top electrode 4. If the distance between the bottom electrode 1 and the top electrode 4 is varied, then a charge outflow will be measured as current via a measuring resistor.

In this case, by way of example, organic electrets on the basis of polymers are used as materials for the charge-storing layer 3. The European Patent Application EP 2 400 515 A discloses an amorphous fluoropolymer under the trade name CYTOP. Furthermore, further polymer-based electrets are also known. By way of example, polytetrafluoroethylene (PTFE) is frequently also used as an electret for MEMS components.

In addition, there are also further approaches with electrets based on inorganic materials. US 3,946,422 discloses, for example, a construction for an MEMS component, silicon dioxide (SiO₂) or titanium dioxide (TiO₂) being mentioned as electret for the charge-storing layer.

In the case of conventional electrets, the charge stored in the charge-storing layer decreases over time. Therefore, the function of the MEMS component can be impaired, for example at high temperatures or high air humidities.

Furthermore, the charge stored in the case of conventional electrets is locally immobile. Therefore, there is the problem that within the charge-storing layer a highly non-uniform distribution can form both into the depth and within the layer plane of the stored charge. Moreover, the confinement energy which has to be applied in order to mobilize charges from the electret is neither very high nor well defined, but rather has a certain energetic distribution. Therefore, a discharge can easily occur, which impairs the long-term stability and reliability of the MEMS component.

Therefore, there is a need for an MEMS component having a charge-storing layer with long-term stability. In particular, there is a need for an MEMS component in which the charge-storing layer has a high temperature and moisture insensitivity.

Furthermore, there is a need for an MEMS component having a charge distribution that is as uniform as possible and well defined both energetically and spatially within a charge-storing layer which, with respect to the surrounding dielectric layers, forms high confinement energy barriers for charges.

### SUMMARY

In accordance with a first aspect, the disclosure provides a microelectromechanical component, comprising a first electrically conductive substrate; a second electrically conductive substrate, which is arranged in a manner spaced apart from the first electrically conductive substrate; a first dielectric layer, which is arranged on a side of the first conductive substrate which faces in the direction of the second electrically conductive substrate; a charge-storing layer, which is arranged on the first dielectric layer; and a second dielectric layer, which is arranged on the charge-storing layer.

In accordance with a further aspect, the present disclosure provides a method for producing a microelectromechanical component comprising the following steps: providing a first electrically conductive substrate; applying a first dielectric layer to the first electrically conductive substrate; applying a charge-storing layer to the first dielectric layer; applying a second dielectric layer to the charge-storing layer; providing a second electrically conductive substrate in a manner spaced apart from the first electrically conductive substrate; applying an electrical voltage between the first electrically conductive substrate and the second electrically conductive substrate; and charging the charge-storing layer.

A concept of the present disclosure involves the charge-storing layer being completely surrounded by electrically insulating, dielectric materials. For this purpose, the charge-storing layer is surrounded by the dielectric layers on both sides. Consequently, the charge-storing layer is no longer separated from the opposite electrode only by an air space, but rather is additionally protected by at least one electrically insulating material.

A considerable advantage is afforded by the fact that it is considerably more difficult for the charge carriers stored in the charge-storing layer to be able to leave the charge-storing layer. Consequently, the charge stored in said charge-storing layer is maintained significantly better. In particular, this also reduces the sensitivity toward loss of charge in an environment with high air humidity and/or temperature.

The fact that, with the construction according to the disclosure, an energetically better defined confinement of the charge carriers within the charge-storing layer can be achieved through the choice of suitable dielectric layers with correspondingly high energy barriers for the charges is also particularly advantageous. This likewise has an advantageous effect on the function of the MEMS component.

In accordance with one embodiment, the charge-storing layer is a polycrystalline layer. A large number of charge carriers can be stored with long-term stability in a polycrystalline layer. Furthermore, the charge carriers can move freely within the polycrystalline layer. A particularly uniform distribution of the stored charge carriers in the layer is thus possible.

In an alternative embodiment, the charge-storing layer is a layer composed of nanocrystals embedded into a dielectric. Such nanocrystals likewise enable electrical charge carriers to be stored with long-term stability.

In a further embodiment, an electrically insulating sealing layer is arranged on the second dielectric layer. Said sealing layer firstly protects the construction situated underneath against mechanical influences. Furthermore, said sealing layer also additionally improves the insulating properties of the second dielectric layer. Consequently, the charge carriers stored in the charge-storing layer are additionally protected.

In a further embodiment, a ferroelectric layer is arranged on the second electrically conductive substrate. Such a ferroelectric layer additionally shields the second electrically conductive substrate from the first electrically conductive substrate with the layers arranged thereon and furthermore also improves the effects arising as a result of the relative movement of the two electrically conductive layers in relation to one another.

In one embodiment, an electrically insulating sealing layer is arranged on the ferroelectric layer. Said sealing layer protects the construction sited underneath. If the MEMS component according to the disclosure does not comprise a ferroelectric layer, said sealing layer can also be applied to the second electrically conductive substrate.

In accordance with one embodiment, in the method for producing an MEMS component, the step for charging the charge-storing layer comprises a step for displacing the first electrically conductive substrate relative to the second electrically conductive substrate. During this displacement of the two substrates, all regions of the construction on the first substrate progressively come into contact with regions on the second substrate. Consequently, all regions of the charge-storing layer can be charged with charge carriers.

In a further embodiment, the method furthermore comprises a step in which a sealing layer is deposited after the step of charging the charge-storing layer. Consequently, said sealing view particularly reliably prevents the stored charge carriers from being discharged.

### BRIEF DESCRIPTION OF THE DRAWINGS

Further features and advantages of the embodiments of the disclosure are evident from the following description with reference to the accompanying drawings.

In the figures:

FIG. 1 shows a schematic illustration of a cross section through an MEMS component in accordance with the prior art;

FIG. 2 shows a schematic illustration of a cross section through an MEMS component in accordance with one embodiment of the present disclosure;

FIG. 3 shows a schematic illustration of a cross section through an MEMS component in accordance with a further embodiment of the disclosure;

FIG. 4 shows a schematic illustration of a cross section through an MEMS component in accordance with a further embodiment of the disclosure;

FIG. 5 shows a schematic illustration of a plan view of an MEMS component in accordance with one embodiment of the present disclosure;

FIG. 6 shows a schematic illustration of a method for producing an MEMS component in accordance with one embodiment of the disclosure.

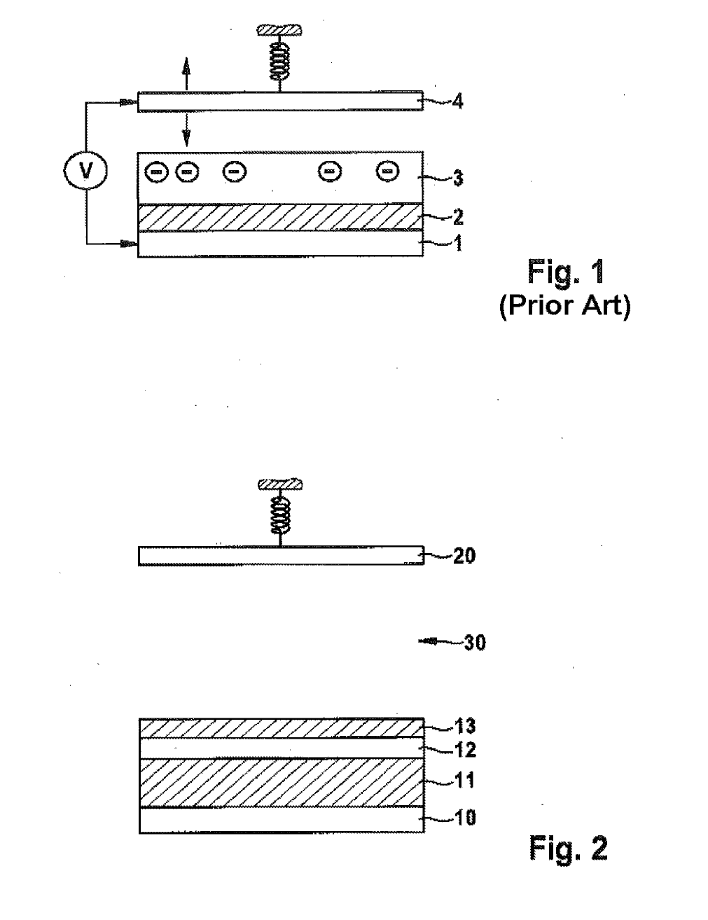

### DETAILED DESCRIPTION

The direction terminology used hereinafter, that is to say terms such as “left”, “right”, “top”, “bottom”, “front”, “back”, “thereabove”, “therebehind” and the like is merely used for a better understanding of the drawings and is not intended under any circumstances to constitute a restriction of the generality. Identical reference signs generally designate components that are of identical type or act identically. The illustrations shown in the figures are in part perspective illustrations of elements which, for reasons of clarity, are not necessarily depicted in a manner true to scale. It goes without saying that the component parts and elements presented in the description and the figures can vary and can be adapted to the respective application within the scope of the consideration of a person skilled in the art.

MEMS components within the meaning of the present disclosure are extremely small components in which an electrical variable and a mechanical movement between two electrically conductive elements are coupled to one another. MEMS components can be regarded firstly as sensors, that is to say components in which a mechanical element is moved and an electrical signal is output in accordance with this movement. By way of example, such a sensor can detect a relative movement between two electrically conductive elements in one, two or three spatial directions and, depending on the movement, can output an electrical variable in the form of a voltage, a current or an emitted quantity of energy. By way of example, such a movement can be the deflection of a microphone membrane. Besides the application as a microphone, MEMS components can also be used as sensors for acceleration, shock, vibrations and much more.

Furthermore, MEMS components within the meaning of the present disclosure likewise encompass actuators. In the case of such actuators, a mechanical movement is effected depending on an applied electrical variable. By way of example, such actuators can be miniaturized drives or the like.

Microelectromechanical components within the meaning of the present disclosure usually have a size of approximately 20 to 30 000 micrometers. However, the described construction of the present disclosure is not necessarily restricted to components of this order of magnitude. Furthermore, the construction according to the disclosure can likewise be used in electromechanical systems whose size deviates upward or downward from the standard values mentioned.

FIG. 2 shows a schematic illustration of a cross section through an MEMS component. A first electrode composed of a first electrically conductive substrate 10 is arranged in the bottom region. Said first electrically conductive substrate 10 is usually connected to the environment in a fixed manner. In principle, however, it is also possible to couple said first substrate 10 to a housing in a movable manner, such that the substrate 10 can be deflected in one or a plurality of spatial directions.

A second electrode composed of an electrically conductive substrate 20 is arranged in the top region of FIG. 2. Said second substrate 20 is usually coupled to the surrounding elements in a movable manner, such that the substrate 20 can be deflected in one or a plurality of spatial directions. If the first substrate 10 is already coupled to the environment in a movable manner, however, the second substrate 20 can also be connected to the environment in a fixed manner. In principle, however, at least one of the two substrates 10, 20 should be arranged in a movable manner.

A first layer 11 composed of a dielectric material is arranged above the first substrate 10, in a manner facing in the direction of the second substrate 20. By way of example, said dielectric layer 11 can be a thin layer composed of silicon dioxide (SiO₂). However, other dielectric materials are likewise possible. The layer thickness of said dielectric layer is usually 50 nanometers or more. By way of example, layer thicknesses of approximately 100 nanometers are particularly suitable.

A layer 12 of a charge-storing material is arranged above said electrically insulating, dielectric layer 11 in a manner facing further in the direction of the second substrate 20. This charge-storing layer 12 can be made very thin. Layer thicknesses of approximately 10 nanometers are possible.

In this case, the charge-storing layer 12 preferably consists of a material in the case of which the charge carriers have to overcome a large potential barrier at the interfaces with the adjacent layers. These potential barriers result from the differences between the work functions of the adjacent layers and that of the charge-storing medium 12.

Such high potential jumps between the adjacent layers ensure very good storage of the charge carriers within the charge-storing layer 12. With a suitable choice of materials, potential barriers can be obtained the level of a few electronvolts (eV).

By way of example, such a charge-storing layer 12 can be formed from a thin polycrystalline film. For example, polycrystalline silicon is very well suited to forming such a thin polycrystalline film. Within this thin polycrystalline film, charge carriers can move freely and be distributed within the charge-storing layer 12. A homogeneous electric field is thus generated within the entire MEMS component.

As an alternative to a polycrystalline film, the charge-storing layer 12 can also be formed from a layer of nanocrystals. Said nanocrystals are preferably embedded in a dielectric, for example SiO₂. A charge-storing layer 12 with high potential barriers relative to the adjoining dielectric layers results in this way, too. Silicon nanocrystals, in particular, are very well suited as nanocrystals. Both a charge-storing layer 12 composed of a polycrystalline film and a dielectric comprising charge-storing nanocrystals enable a large number of charge carriers to be stored with long-term stability.

A second electrically insulating, dielectric layer 13 is arranged above the charge-storing layer 12 in a manner facing further in the direction of the second substrate 20. Consequently, the charge-storing layer 12 is completely surrounded by the electrically insulating, dielectric layers 11 and 13, wherein the first dielectric layer 11 is thicker than the second dielectric layer 13 in order to prevent the charges from tunneling out or further into the first subtrate 10. This second insulating layer 13 can also be formed from SiO₂, for example.

Furthermore, an air space 30 is also situated between the described construction and the second substrate 20. Since at least one of the two substrates 10, 20 is arranged in a movable manner, said air space 30 enables the first and second substrates 10, 20 to be movable in relation to one another.

In order then to introduce charge carriers into the charge-storing layer 12, the second electrically conductive substrate 20 is brought into contact with the second dielectric layer 13. A voltage is thereupon applied between the first substrate 10 and the second substrate 20, said voltage having a magnitude such that the charge carriers can overcome the potential barriers between the charge-storing layer 12 and the adjacent layers 11, 13 and charge carriers are injected through the dielectric into the charge-storing layer 12.

If the applied voltage is thereupon removed again, then the charge carriers remain within the charge-storing layer 12. On account of the high potential barrier between the charge-storing layer 12 and the adjoining dielectric layers 11, 13, this results in charge storage with good long-term stability and very low sensitivity to high temperatures and high air humidity.

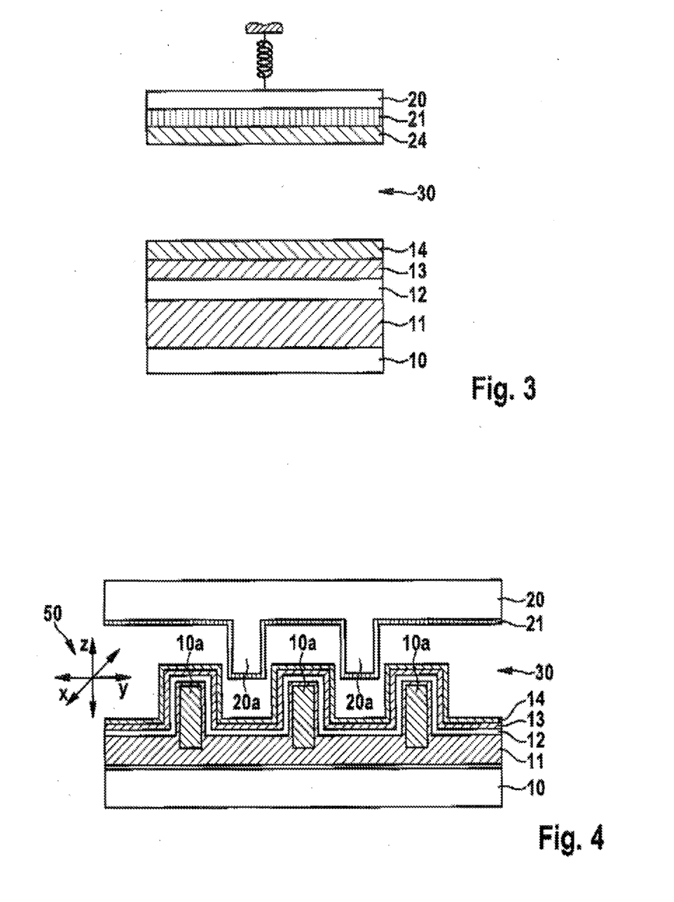

In this case, the charge-storing properties of the layer 12 can also additionally be improved by additional sealing being effected after the charge carriers have been introduced into the charge-storing layer 12. As illustrated in FIG. 3, for this purpose, after the charge-storing layer 12 has been charged, an additional sealing layer 14 and 24 can respectively be applied to the second dielectric layer 13 and, if appropriate, also to the second substrate 20. These sealing layers are further, thin dielectric layers composed of Al₂O₃ or SiO₂, for example. The probability of tunneling through a dielectric layer decreases with increasing thickness. Said additional sealing layer therefore significantly reduces the probability of charges tunneling from the charge-storing layer 12. In order to avoid a discharge of the charge-storing layer 12 during the coating with the sealing layer, said sealing layers 14, 24 should be applied preferably at low temperatures of below 300° C. e.g. by means of an ALD (atomic layer deposition) method. The low deposition temperature is essential here in order to prevent the charges previously injected into the charge-storing layer 12 from flowing away.

Furthermore, the function of the MEMS component can also additionally be improved by a further ferroelectric layer 21 composed of a ferroelectric material or a material having a high dielectric constant being applied to the top substrate 20, in a manner facing in the direction of the bottom substrate 10. Such a ferroelectric layer 21 on the top substrate 20 can improve the effectiveness. Consequently, it is possible to increase for example the electrical energy or currents output depending on the relative movement between the two substrates 10, 20.

If the substrate 20 is provided with such a further layer 21, then the sealing layer 24 described above can be applied to this additional ferroelectric layer 21.

FIG. 4 shows a further embodiment of the present disclosure. In order to increase the effectiveness of the MEMS component, the first and second substrates 10a, 20a are in this case configured in a comb-like manner. In comparison with a planar embodiment of the substrates 10a, 20a, this results in an increase in the effective capacitance. Furthermore, such a configuration of the substrates makes it possible also to identify a movement in more than one spatial direction. Particularly if not all of the structures of the substrates 10a, 20a run parallel to one another, it is possible to evaluate a relative movement in relation to one another in all three spatial directions.

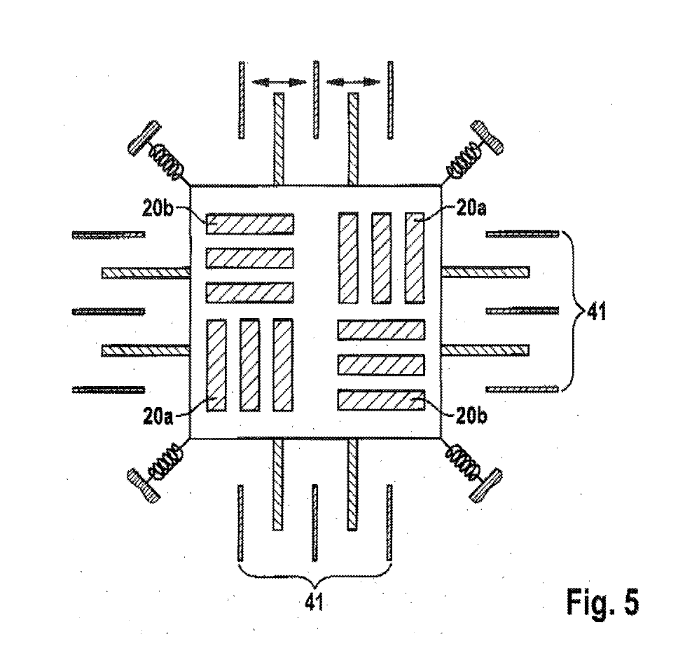

FIG. 5 shows a schematic plan view of an MEMS component having an above-described structuring of the substrates. By means of different orientation of the substrate elements 20a and 20b, movements in all three spatial directions can thus be detected and evaluated differently.

In this case, too, in order to introduce charge carriers into the charge-storing layer 12, the top substrate 20a has to be brought into contact with the second dielectric layer 13 and a voltage of suitable magnitude has to be applied. If a material composed of polycrystalline film is used in this case as the charge-storing layer 12, then it suffices to produce the contact between substrate 20a and dielectric layer 13 at least one location. The charge carriers introduced into the layer 12 can thereupon be independently distributed uniformly within the entire charge-storing layer 12.

By contrast, if a layer of individual nanocrystals is used as the charge-storing layer 12, then the charge has to be introduced separately into each individual nanocrystal since the individual nanocrystals are bound in a dielectric carrier matrix and, consequently, no charge carrier exchange is possible between the individual nanocrystals.

This necessitates a whole-area contact between substrate 20a, 20b and the second dielectric layer 13. In the case of the comb-like structure of the substrate 20a as illustrated in FIG. 4, however, it is not possible to produce a whole-area contact with the second dielectric layer 13 by simply lowering the substrate. Rather, in this case, the top substrate 20a, 20b also additionally has to be deflected in the two remaining spatial directions, that is to say in the x- and y-directions in accordance with the coordinate system 50. Consequently, progressively the complete surface of the second dielectric layer 13 can be brought into contact with the second substrate 20a, 20b and, consequently, each individual nanocrystallite of the charge-storing layer 12 can be charged with charge carriers.

In order to enable this deflection in the x- and y-directions, it is possible, as illustrated in FIG. 5, for the movable electrode also additionally to be provided with a suitable deflection device 41. By way of example, this can involve comb-like electrodes which cause a corresponding deflection after a suitable voltage has been applied.

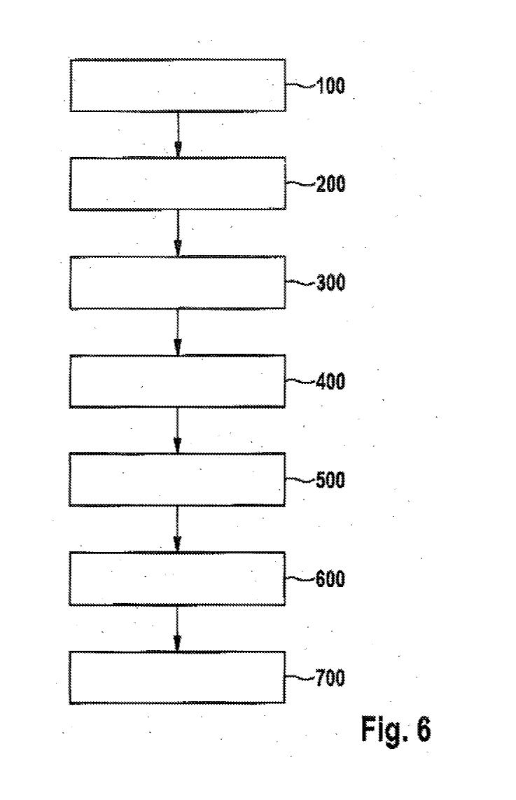

FIG. 6 shows a schematic illustration of a method for producing an MEMS component according to the disclosure. In a first step 100, firstly a first electrically conductive substrate 10 is provided. In a further step 200, a first dielectric layer 11 is applied to said electrically conductive substrate 10. Afterward, in a further step 300, a charge-storing layer 12 is applied to the first dielectric layer 11. Afterward, in a further step 400, a second electric layer 13 is applied to the charge-storing layer 12. In a further step 500, however, a second electrically conductive substrate 20 is provided. Subsequently, in a step 600, an electrical voltage is applied between the first electrically conductive substrate 10 and the second electrically conductive substrate 20 and, in a step 700, the charge-storing layer 12 is charged.

In the case of a comb-like substrate structure described above, step 700 for charging the charge-storing layer 12 also comprises, in particular, the possibly required deflection of the second conductive substrate 20 in the required spatial directions. This enables complete charging of all charge-storing elements in the charge-storing layer 12.

Optionally, the method can also furthermore comprise an additional step for applying a ferroelectric layer 21 to the second electrically conductive substrate 20.

Likewise optionally, the method can comprise a further step for applying a sealing layer 14, 24. Said sealing layer, for improving the long-term stability of the charge-storing layer 12, is finally applied to the free surface of the second dielectric layer 13 and, if appropriate, also to the surface of the second electrically conductive substrate 20 or to the ferroelectric layer 21.

To summarize, the present disclosure relates to an MEMS component and a method for producing an MEMS component with an improved long-term stability of the charge-storing layer. For this purpose, a charge-storing layer is completely enclosed by dielectric layers, such that there is a high potential barrier between charge-storing layer and dielectric layers. During normal operation, it is not possible to overcome this high potential barrier, as a result of which the stored charge carriers are maintained over a very long period of time.

What is claimed is:

1. A microelectromechanical component, comprising:
a first electrically conductive substrate;
a second electrically conductive substrate arranged in a manner spaced apart from the first electrically conductive substrate;
a first dielectric layer arranged on a side of the first conductive substrate which faces in the direction of the second electrically conductive substrate;
a charge-storing layer arranged on the first dielectric layer; and
a second dielectric layer arranged on the charge-storing layer.

2. The microelectromechanical component according to claim 1, wherein the charge-storing layer is a polycrystalline layer.

3. The microelectromechanical component according to claim 1, wherein the charge-storing layer is a layer composed of nanocrystallites embedded into a dielectric.

4. The microelectromechanical component according to claim 1, further comprising a first electrically insulating sealing layer arranged on the second dielectric layer.

5. The microelectromechanical component according to claim 1, further comprising a ferroelectric layer arranged on a side of the second electrically conductive substrate which faces in the direction of the first conductive substrate.

6. The microelectromechanical component according to claim 5, further comprising a second electrically insulating sealing layer arranged on the ferroelectric layer.

7. A method for producing a microelectromechanical component, comprising:
applying a first dielectric layer to a first electrically conductive substrate;
applying a charge-storing layer to the first dielectric layer;
applying a second dielectric layer to the charge-storing layer;
applying an electrical voltage between the first electrically conductive substrate and a second electrically conductive substrate spaced apart from the first electrically conductive substrate; and
charging the charge-storing layer.

8. The method for producing a microelectromechanical component according to claim 7, wherein charging the charge-storing layer comprises displacing the first electrically conductive substrate relative to the second electrically conductive substrate.

9. The method for producing a microelectromechanical component according to claim 7, wherein a sealing layer is deposited after charging the charge-storing layer.
